(19) United States
(12) Patent Application Publication
(10) Pub. No.: US 2026/0136582 A1
(43) Pub. Date: May 14, 2026

(54) VERTICAL STRUCTURE SEMICONDUCTOR DEVICE AND METHOD OF MANUFACTURING THE SAME

(71) Applicant: Samsung Electronics Co., Ltd., Suwon-si (KR)

(72) Inventors: Baekwon PARK, Suwon-si (KR); Minseok YOO, Suwon-si (KR); Minhyun LEE, Suwon-si (KR)

(73) Assignee: Samsung Electronics Co., Ltd., Suwon-si (KR)

(21) Appl. No.: 19/196,632

(22) Filed: May 1, 2025

(30) Foreign Application Priority Data
Nov. 12, 2024 (KR) 10-2024-0160492

(51) Int. Cl. H10D 30/47; H10D 30/01; H10D 62/80

(52) U.S. Cl. CPC H10D 30/485; H10D 30/017; H10D 62/883

(57) ABSTRACT

A vertical structure semiconductor device may include a first electrode layer including a transition metal element, a mask layer including a metal oxide where the mask layer may be on the first electrode layer and may expose a portion of a surface of the first electrode layer through channel growth regions in the mask layer, channels each including a transition metal dichalcogenide, a first gate electrode on the mask layer and surrounding each of the channels, a gate insulating layer on the mask layer and between the first gate electrode and the channels, and a second electrode layer. A first end of the channels may be on the portion of the surface of first electrode layer. The second electrode layer may contact a second end of the channels. The transition metal dichalcogenide of the channels may include the transition metal element of the first electrode layer.

### CROSS-REFERENCE TO RELATED APPLICATION

This application is based on and claims priority under 35 U.S.C. § 119 to Korean Patent Application No. 10-2024-0160492, filed on Nov. 12, 2024 in the Korean Intellectual Property Office, the disclosure of which is incorporated by reference herein in its entirety.

### BACKGROUND

### 1. Field

The disclosure relates to a vertical structure semiconductor device and/or a method of manufacturing the same.

### 2. Description of the Related Art

Two-dimensional materials are in the spotlight as new materials for semiconductor device scaling. Among them, transition metal dichalcogenide (TMD) is being studied because of its semiconductor properties.

### SUMMARY

In a vertical structure semiconductor device including a channel including of a transition metal dichalcogenide, a vertical structure semiconductor device including a channel may be formed by direct growth from an electrode surface may be provided.

A chalcogen precursor may be supplied through a mask layer providing a channel growth region to induce channel growth, and thereby, a channel including a transition metal dichalcogenide may be grown.

Additional aspects will be set forth in part in the description which follows and, in part, will be apparent from the description, or may be learned by practice of the presented embodiments of the disclosure.

According to an embodiment, a vertical structure semiconductor device may include a first electrode layer including a transition metal element; a mask layer including a metal oxide, the mask layer on the first electrode layer, the mask layer exposing a portion of a surface of the first electrode layer through a plurality of channel growth regions in the mask layer; a plurality of channels each including a transition metal dichalcogenide, a first end of the plurality of channels being on the portion of the surface of the first electrode layer exposed by the plurality of channel growth regions; a first gate electrode on the mask layer and surrounding each of the plurality of channels; a gate insulating layer on the mask layer, the gate insulating layer between the first gate electrode and the plurality of channels; and a second electrode layer contacting a second end of the plurality of channels, the second end of the plurality of channels being opposite the a first end of the plurality of channels. The transition metal dichalcogenide of the plurality of channels may include a transition metal element of the first electrode layer.

In some embodiments, the plurality of channels may be grown on the first electrode layer by supplying a precursor including a chalcogen element on the plurality of channel growth regions of the mask layer.

In some embodiments, the transition metal element may include at least one of Mo, W, Nb, V, Ta, Ti, Zr, Hf, Co, Tc, Cu, Ni, Rh, Pd, Ir, Zn, Pt, and Re.

In some embodiments, the transition metal dichalcogenide of the plurality of channels may include at least one of S, Se, and Te.

In some embodiments, the plurality of channels may include a first transition metal dichalcogenide and a second transition metal dichalcogenide. The second transition metal dichalcogenide may be different from the first transition metal dichalcogenide.

In some embodiments, the first transition metal dichalcogenide and the second transition metal dichalcogenide may include a same transition metal element.

In some embodiments, one of the first transition metal dichalcogenide and the second transition metal dichalcogenide may include a p-type semiconductor, and an other of the first transition metal dichalcogenide and the second transition metal dichalcogenide may include an n-type semiconductor.

In some embodiments, a thickness of the mask layer may be greater than 0 and less than or equal to 10 nm.

In some embodiments, the metal oxide of the mask layer may include at least one of Hf, Al, and Zr.

In some embodiments, the gate insulating layer may include a same metal oxide as the metal oxide of the mask layer.

In some embodiments, the plurality of channels may include at least one of nano rods and nano sheets.

According to an embodiment, a method of manufacturing a vertical structure semiconductor device may include preparing a first electrode layer including a transition metal element; forming a mask layer on the first electrode layer, the mask layer exposing a portion of a surface of the first electrode layer through a plurality of channel growth regions; growing a plurality of channels by supplying a precursor including a chalcogen element on the plurality of channel growth regions; forming a gate electrode and a gate insulating layer on the mask layer; and forming a second electrode layer on the plurality of channels. The plurality of channels may include a transition metal dichalcogenide including the transition metal element of the first electrode layer.

In some embodiments, the transition metal element may include at least one of Mo, W, Nb, V, Ta, Ti, Zr, Hf, Co, Tc, Cu, Ni, Rh, Pd, Ir, Zn, Pt, and Re.

In some embodiments, the transition metal dichalcogenide may include at least one of S, Se, and Te.

In some embodiments, the plurality of channels may include a first transition metal dichalcogenide and a second transition metal dichalcogenide. The second transition metal dichalcogenide may be different from the first transition metal dichalcogenide.

In some embodiments, the growing the plurality of channels may include: growing a first channel including the first transition metal dichalcogenide by supplying the first precursor including the first chalcogen element; and growing a second channel including the second transition metal dichalcogenide by supplying the second precursor including the second chalcogen element. The second chalcogen element may be different from the first chalcogen element.

In some embodiments, one of the first channel and the second channel may include a p-type semiconductor and an other the first channel and the second channel may include an n-type semiconductor.

In some embodiments, each of the first channel and the second channel may include the transition metal element of the first electrode layer.

In some embodiments, in the forming the mask layer, a metal oxide including at least one of Hf, Al, and Zr may be formed on the first electrode layer.

In the forming the mask layer, the mask layer may be formed on the first electrode layer. A thickness of the mask layer may be greater than 0 and less than or equal to 10 nm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view conceptually illustrating a vertical structure semiconductor device according to an embodiment;

FIG. 2 is a perspective view conceptually illustrating a vertical structure semiconductor device according to an embodiment;

FIG. 3 is a perspective view conceptually illustrating a vertical structure semiconductor device according to an embodiment;

FIG. 4 is a plan view of a vertical structure semiconductor device according to an embodiment;

FIG. 5 is a cross-sectional view of a vertical structure semiconductor device according to an embodiment;

FIG. 6 is a cross-sectional view of a vertical structure semiconductor device according to an embodiment;

FIG. 7 is a cross-sectional view illustrating a vertical structure semiconductor device including different types of channels, according to an embodiment;

FIG. 8 is a perspective view illustrating a vertical structure semiconductor device including different types of channels, according to an embodiment;

FIG. 9 is a flowchart illustrating a method of manufacturing a vertical structure semiconductor device, according to an embodiment;

FIG. 10 is a diagram illustrating an operation of forming a mask layer;

FIG. 11 is a diagram illustrating an operation of growing a plurality of channels;

FIG. 12 is a diagram illustrating an operation of forming a gate electrode and an insulating layer;

FIG. 13 is a flowchart illustrating a method of manufacturing a vertical structure semiconductor device, according to an embodiment;

FIG. 14 is a diagram illustrating an operation of growing a first channel, according to an embodiment; and

FIG. 15 is a diagram illustrating an operation of growing a second channel, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Hereinafter, embodiments will be described in detail with reference to the accompanying drawings. In the following drawings, the same reference numerals refer to the same components, and the size of each component in the drawings may be exaggerated for clarity and convenience of description. In addition, the embodiments described below are merely non-limiting examples and various modifications are possible from these embodiments. Hereinafter, the term “on”, “upper portion/lower portion” or “above/below” may also include “to be present above/below on a non-contact basis” as well as “to be present above/below on a direct contact basis”. The singular expression includes plural expressions unless the context clearly implies otherwise. In addition, when a part “includes” a component, this means that it may further include other components, not excluding other components unless otherwise stated. The use of the term “the” and similar indicative terms may correspond to both singular and plural. If there is no explicit description or contrary description of the order of the steps or operations constituting the method, these steps or operations may be carried out in an appropriate order and are not necessarily limited to the described order. Further, the terms “unit”, “module” or the like mean a unit that processes at least one function or operation, which may be implemented in hardware or software or implemented in a combination of hardware and software. The connection or connection members of lines between the components shown in the drawings exemplarily represent functional connection and/or physical or circuit connections, and may be replaceable or represented as various additional functional connections, physical connections, or circuit connections in an actual device. The use of all examples and terms below is simply to describe technical ideas in detail, and the scope is not limited by these examples or terms unless the scope is limited by the claims.

Hereinafter, a vertical structure semiconductor device and a method of manufacturing the vertical structure semiconductor device, according to embodiments, will be described in more detail.

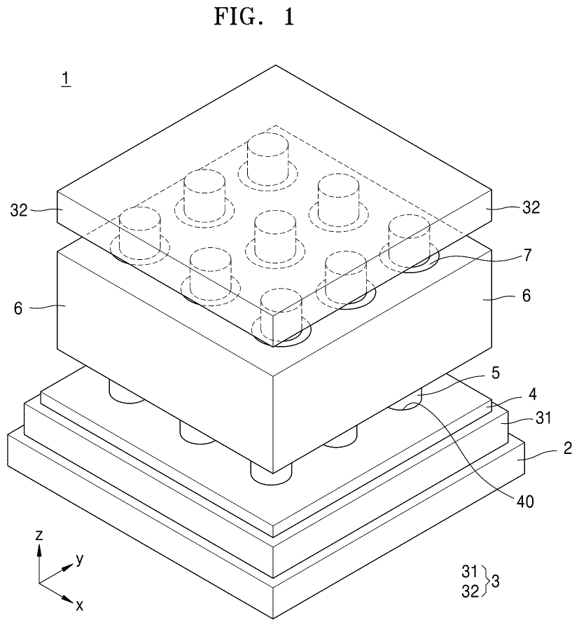

FIG. 1 is a perspective view conceptually illustrating a vertical structure semiconductor device 1 according to an embodiment.

Referring to FIG. 1, a vertical structure semiconductor device 1 according to an embodiment may include a substrate 2. The substrate 2 may include at least one of silicon, silicon oxide, aluminum oxide, magnesium oxide, silicon carbide, silicon nitride, glass, quartz, sapphire, graphite, graphene, polyimide copolymer, polyimide, polyethylene naphthalate (PEN), fluorinated ethylene propylene (FEP), and polyethylene terephthalate (PET). However, the above description is merely an example of a material of the substrate 2, but is not limited thereto.

The vertical structure semiconductor device 1 according to an embodiment may include an electrode layer 3. The electrode layer 3 may include a source electrode and a drain electrode. The electrode layer 3 may include a first electrode layer 31 and a second electrode layer 32. One of the first electrode layer 31 and the second electrode layer 32 may be a source electrode and the other may be a drain electrode. The first electrode layer 31 may be arranged on the substrate 2. The second electrode layer 32 may be arranged above the first electrode layer 31. A channel 5 to be described later may be arranged between the first electrode layer 31 and the second electrode layer 32. The first electrode layer 31, the channel 5, and the second electrode layer 32 may be arranged in a row. The first electrode layer 31, the channel 5, and the second electrode layer 32 may be sequentially arranged in a direction perpendicular to the substrate 2. Each of the first electrode layer 31 and the second electrode layer 32 may be electrically connected to the channel 5.

The electrode layer 3 according to an embodiment may include an electrically conductive material. The electrode layer 3 may include a metal or a metal compound. The electrode layer 3 may include a transition metal element. The electrode layer 3 may include at least one of, for example, Mo, W, Nb, V, Ta, Ti, Zr, Hf, Co, Tc, Cu, Ni, Rh, Pd, Ir, Zn, Pt, and Re. The first electrode layer 31 and the first electrode layer 31 may include the same material, but are not limited thereto. However, the description of the electrode layer 3 is merely an example, and the disclosure is not limited thereto.

The vertical structure semiconductor device 1 according to an embodiment may include a plurality of channels 5. The channel 5 may provide a path for moving charges between the first electrode layer 31 and the second electrode layer 32. The channel 5 may be electrically connected to the first electrode layer 31 and the second electrode layer 32. The first electrode layer 31 and the second electrode layer 32 may be arranged at both ends of the channel 5, respectively. The first electrode layer 31 may be in contact with the channel 5 at one end of the channel 5. The second electrode layer 32 may be in contact with the channel 5 at the other end of the channel 5 opposite to one end of the channel 5 in contact with the first electrode layer 31. The electrode layer 3 may be arranged to be in edge contact with the channel 5. More specifically, each of the first electrode layer 31 and the second electrode layer 32 may be arranged to be in planar contact with the channel 5. The channel 5 may be arranged in a direction perpendicular to the first electrode layer 31. The channel 5 may extend in a direction perpendicular to the first electrode layer 31. However, the above description of the arrangement and function of the channel 5 and the electrode layer 3 is for illustrative purposes only and is not limited thereto.

The channel 5 according to an embodiment may include a two-dimensional semiconductor material. For example, the channel 5 may include a transition metal dichalcogenide. The transition metal dichalcogenide included in the channel 5 may include the same transition metal element as the transition metal element included in the first electrode layer 31. The chalcogen element of the transition metal dichalcogenide included in the channel 5 may include at least one of S, Se, and Te, but is not limited thereto. The transition metal dichalcogenide may include, for example, but is not limited to, MoS₂, MoSe₂, MoTe₂, WS₂, WSe₂, WTe₂, ZrS₂, ZrSe₂, HfS₂, HfSe₂, NbSe₂, or ReSe₂.

The channel 5 may include an n-type semiconductor material and/or a p-type semiconductor material. Some of the plurality of channels 5 may include an n-type semiconductor material, and the rest may include a p-type semiconductor material. However, embodiments are not limited thereto, and all of the plurality of channels 5 may include an n-type semiconductor material, or all of the plurality of channels 5 may include a p-type semiconductor material.

The vertical structure semiconductor device 1 according to an embodiment may include a mask layer 4. The mask layer 4 may be arranged on the first electrode layer 31. The mask layer 4 may include a metal oxide. The metal oxide included in the mask layer 4 may include at least one metal element from among Hf, Al, and Zr. The metal oxide included in the mask layer 4 may include, for example, hafnium oxide, zirconium oxide, and aluminum oxide. However, embodiments are not limited thereto, and may include a metal oxide composed of a ternary system such as hafnium-zirconium oxide.

The mask layer 4 according to an embodiment may include a channel growth region 40 that provides a space for the channel 5 to grow, by exposing a portion of the surface of the first electrode layer 31. The channel 5 may be formed by growing in a direction perpendicular to the substrate 2 from the surface of the first electrode layer 31, and more specific details will be described later.

The vertical structure semiconductor device 1 according to an embodiment may include a gate electrode 6. The gate electrode 6 may be arranged above the mask layer 4. The gate electrode 6 may be arranged to surround each of the plurality of channels 5. The gate electrode 6 surrounds the channel 5 in the entire region of a plane (xy plane) perpendicular to the direction (z direction) in which the channel 5 extends, and the vertical structure semiconductor device 1 may have a gate-all-round structure. However, this is only an illustrative description and embodiments are not limited thereto.

The vertical structure semiconductor device 1 according to an embodiment may include a gate insulating layer 7. The gate insulating layer 7 may be arranged on the mask layer 4. The gate insulating layer 7 may be arranged between the gate electrode 6 and the plurality of channels 5. The gate insulating layer 7 may provide an insulating function between the gate electrode 6 and the channel 5. However, the description of the function and arrangement of the gate insulating layer 7 is only an illustrative description and embodiments are not limited thereto.

The gate insulating layer 7 according to an embodiment may include a metal oxide. The metal oxide included in the gate insulating layer 7 may include at least one metal element among Hf, Al, and Zr. The gate insulating layer 7 may include the same metal oxide as the metal oxide included in the mask layer 4. The gate insulating layer 7 may include the same material as the material of the mask layer 4, but embodiments are not limited thereto.

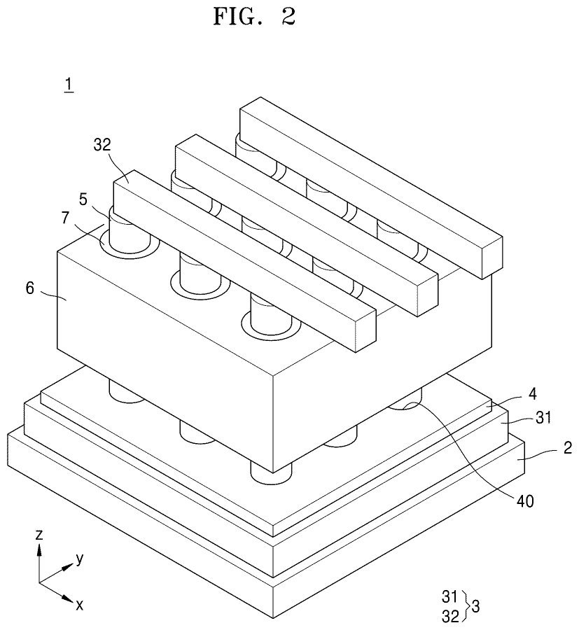

FIG. 2 is a perspective view conceptually illustrating a vertical structure semiconductor device 1 according to an embodiment.

Referring to FIGS. 1 and 2, there may be a plurality of second electrode layers 32 according to an embodiment. Each of the plurality of second electrode layers 32 may be selectively connected to a plurality of channels 5, but embodiments are not limited thereto.

Hereinafter, for convenience of description, the vertical structure semiconductor device 1 having the plurality of second electrode layers 32 will be mainly described. The technical idea of the disclosure is not limited thereto, and a separate embodiment which may be sufficiently obtained through a design change by those skilled in the art may also belong to a technical idea of the disclosure.

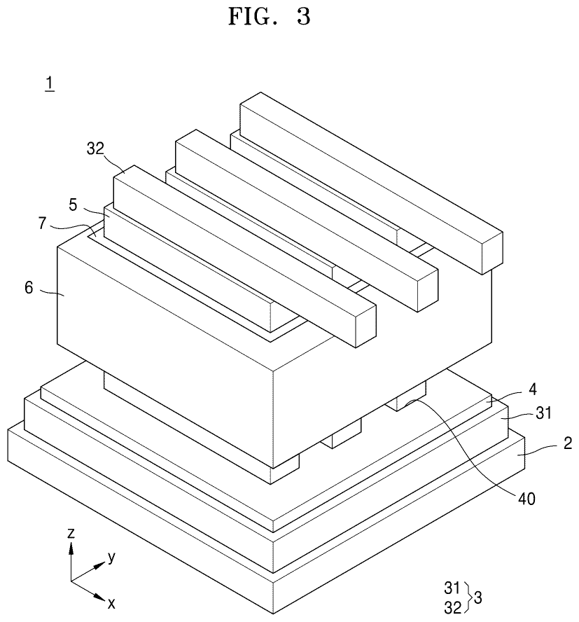

FIG. 3 is a perspective view conceptually illustrating a vertical structure semiconductor device 1 according to an embodiment.

Referring to FIGS. 1 to 3, a plurality of channels 5 according to an embodiment may include at least one type of nano rods and nano sheets. When the plurality of channels 5 include nano sheets, the vertical structure semiconductor device 1 may have a multi-bridge channel FET (MBCFET) structure, but embodiments are not limited thereto.

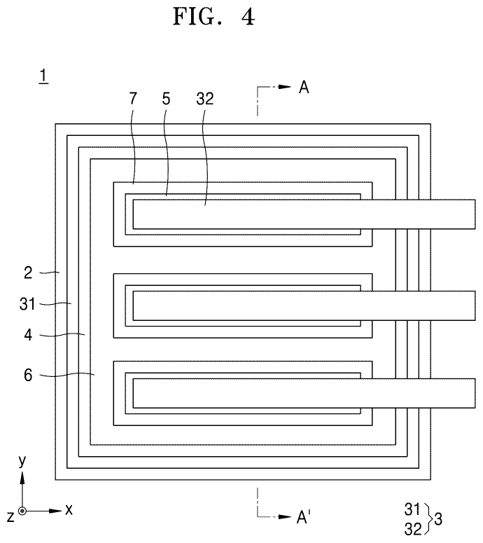

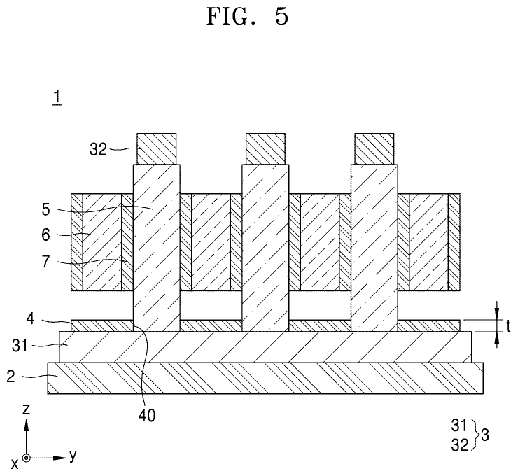

FIG. 4 is a plan view of a vertical structure semiconductor device 1 according to an embodiment. FIG. 5 is a cross-sectional view of a vertical structure semiconductor device 1 according to an embodiment. FIG. 5 may be a cross-sectional view of the vertical structure semiconductor device 1 shown in FIG. 4, viewed in a direction A-A′. Meanwhile, in the drawing shown in FIG. 4 and the drawings following FIG. 4, the size ratio or arrangement of each component may be different from those of the drawings illustrated in FIGS. 1 to 3. These are not mutually contradictory and may be exaggerated or emphasized to facilitate the conceptual explanation of a particular configuration.

Referring to FIGS. 2 to 5, the mask layer 4 according to an embodiment may include a plurality of channel growth regions 40. The channel growth region 40 may be a region in which the mask layer 4 exposes a portion of the surface of the first electrode layer 31 upwardly. The mask layer 4 may expose a portion of the surface of the first electrode layer 31 through the plurality of channel growth regions 40. Here, the mask layer 4 exposing a portion of the surface of the first electrode layer 31 may provide a region in which the channel 5 may be in contact with the first electrode layer 31. The mask layer 4 exposing a portion of the surface of the first electrode layer 31 may provide a region in which the channel 5 may grow. In other words, the mask layer 4 may provide a channel growth region 40 that induces the growth of the channel 5 so that the channel 5 may grow in a vertical direction from the surface of the first electrode layer 31.

By supplying a precursor including a chalcogen element on the plurality of channel growth regions 40 of the mask layer 4 according to an embodiment, the plurality of channels 5 may grow upwardly from the surface of the first electrode layer 31. The plurality of channels 5 may be grown by supplying a precursor including a chalcogen element on the plurality of channel growth regions 40 of the mask layer 4. The precursor provided on the channel growth region 40 may include, for example, at least one of S, Se, and Te, but embodiments are not limited thereto.

The first electrode layer 31 according to an embodiment may include a transition metal element, and the plurality of channels 5 may include a transition metal dichalcogenide. The transition metal dichalcogenide included in the plurality of channels 5 may include a transition metal element of the first electrode layer 31. The first electrode layer 31 may supply a transition metal element to the plurality of channels 5 so that the plurality of channels 5 may grow. As a result of the first electrode layer 31 supplying transition metal elements for the plurality of channels 5 to grow, the transition metal dichalcogenide included in the channels 5 may include the same transition metal elements as the transition metal elements included in the first electrode layer 31. The transition metal element forming the transition metal dichalcogenide included in the channel 5 may include at least one of Mo, W, Nb, V, Ta, Ti, Zr, Hf, Co, Tc, Cu, Ni, Rh, Pd, Ir, Zn, Pt, and Re, but embodiments are not limited thereto. The chalcogen element of the transition metal dichalcogenide included in the channel 5 may include at least one of S, Se, and Te, but is not limited thereto.

A precursor including a chalcogen element reacts with a transition metal of the first electrode layer 31 through the plurality of channel growth regions 40 of the mask layer 4 according to an embodiment, and thus, the plurality of channels 5 may be grown across the channel growth regions 40, respectively. In other words, the plurality of channels 5 may be grown higher than the top end of the mask layer 4 across the channel growth regions 40 of the mask layer 4, respectively. However, the description of the function and role of the mask layer 4 is merely an example, and embodiments are not limited thereto.

The thickness t of the mask layer 4 according to an embodiment may be greater than 0 and less than or equal to about 10 nm. The thickness t of the mask layer 4 may be greater than 0 and less than or equal to about 5 nm. The thickness t of the mask layer 4 may be greater than 0 and less than or equal to about 3 nm. However, the thickness t of the mask layer 4 is not limited thereto, and conditions for growing the plurality of channels 5 may be diversified by adjusting the thickness t of the mask layer 4 depending on the process. In addition, the lengths of the plurality of channels 5 may be adjusted by adjusting the supply method or supply time of precursors including chalcogen elements supplied through the channel growth regions 40 of the mask layer 4.

The vertical structure semiconductor device 1 according to an embodiment includes the mask layer 4 that provides the channel growth regions 40 so that the plurality of channels 5 may grow directly, and thus, the vertical structure semiconductor device 1 may be provided with few defects in the contact surfaces of the channels 5. More specifically, it is possible to provide a vertical structure semiconductor device 1 with excellent metal-substrate bonding between the electrode layer 3 and the channels 5.

The gate insulating layer 7 according to an embodiment may be formed after the plurality of channels 5 have been grown. The gate insulating layer 7 may be formed to surround each of the plurality of channels 5 after the growth of the plurality of channels 5 has been completed. The gate insulating layer 7 is formed after the growth of the plurality of channels 5 has been completed, and thus, the interface between each of the channels 5 and the gate insulating layer 7 may be clearly defined. In other words, it is possible to provide the vertical structure semiconductor device 1 having excellent electrical characteristics such as limiting and/or minimizing the current leakage of the channels 5 as transition of the interface between each of the channels 5 and the gate insulating layer 7 is abrupt. In addition, it is possible to provide the semiconductor device having improved or excellent adhesion between each of the channels 5 and the gate insulating layer 7, thereby providing the vertical structure semiconductor device 1 having improved or excellent electrical characteristics.

The gate electrode 6 according to an embodiment may be formed to surround each of the plurality of channels 5 after the gate insulating layer 7 has been formed. In this case, by adjusting the number of gate electrodes 6 to be formed, it is possible to provide a vertical structure semiconductor device 1 that may be used for static RAM.

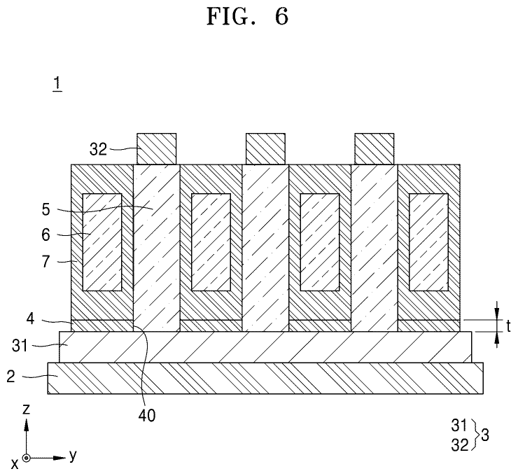

FIG. 6 is a cross-sectional view of a vertical structure semiconductor device 1 according to an embodiment.

Referring to FIGS. 2 to 6, the gate insulating layer 7 according to an embodiment may be arranged on the mask layer 4. The gate insulating layer 7 may be formed to fill a space between the mask layer 4 and the gate electrode 6. The gate insulating layer 7 may include the same material as that of the mask layer 4, and for example, the material of the gate insulating layer 7 and the material of the mask layer 4 may include a hafnium oxide material. The gate insulating layer 7 may be formed after the mask layer 4 has been formed, but the gate insulating layer 7 and the mask layer 4 may form substantially one body. However, this is only an illustrative description and embodiments are not limited thereto.

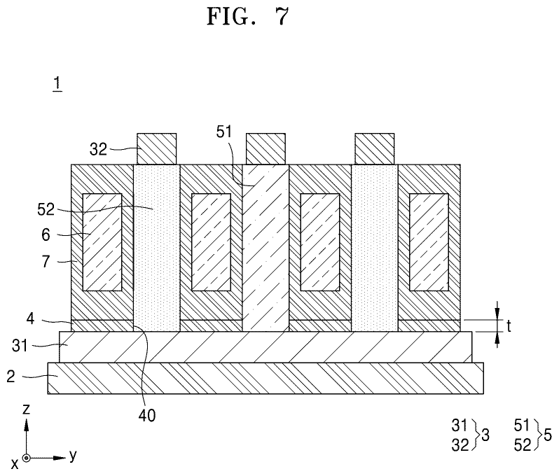

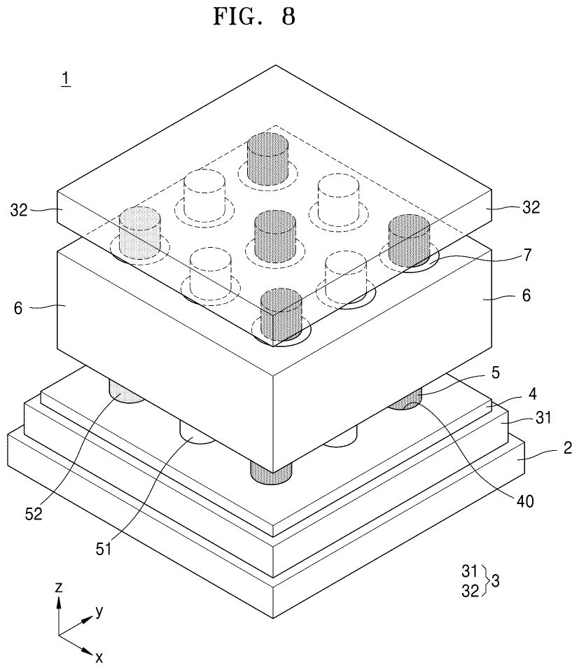

FIG. 7 is a cross-sectional view illustrating a vertical structure semiconductor device 1 including different types of channels 5 according to an embodiment. FIG. 8 is a perspective view illustrating a vertical structure semiconductor device 1 including different types of channels 5 according to an embodiment. Hereinafter, redundant descriptions with those described above will be omitted, and differences will be mainly described.

Referring to FIGS. 1 to 8, a plurality of channels 5 according to an embodiment may include different types of channels 5. The plurality of channels 5 may include a first transition metal dichalcogenide and a second transition metal dichalcogenide different from the first transition metal dichalcogenide. One of the first transition metal dichalcogenide and the second transition metal dichalcogenide may include a p-type semiconductor and the other may include an n-type semiconductor. The type of the chalcogen precursor supplied to the channel growth region 40 of the mask layer 4 is controlled according to the process conditions, and thus, the plurality of channels 5 including different types of transition metal dichalcogenide may be formed. For example, the first transition metal dichalcogenide may be grown by supplying a chalcogen precursor including sulfur, and the second transition metal dichalcogenide may be grown by supplying a chalcogen precursor including selenium. In this case, the first transition metal dichalcogenide and the second transition metal dichalcogenide may be supplied with the transition metal element by the first electrode layer 31 during the growth process. The first transition metal dichalcogenide and the second transition metal dichalcogenide included in the plurality of channels 5 may include the same transition metal element. For example, the first transition metal dichalcogenide may include WS₂, and the second transition metal dichalcogenide may contain WSe₂, but embodiments are not limited thereto.

The vertical structure semiconductor device 1 according to an embodiment may include channels 5 having both n-type semiconductor and p-type semiconductor characteristics. The vertical structure semiconductor device 1 may be implemented to have excellent integration with NMOS and PMOS arrays through the channel growth regions 40 of the mask layer 4 capable of directly growing the plurality of channels 5.

Hereinafter, a method of manufacturing a vertical structure semiconductor device according to an embodiment will be described. Hereinafter, redundant descriptions with those described above will be omitted, and differences will be mainly described.

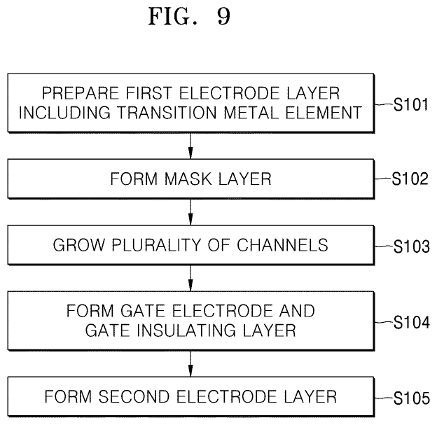

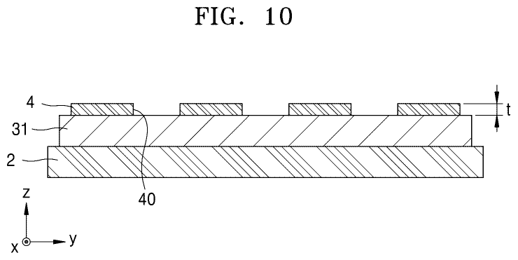

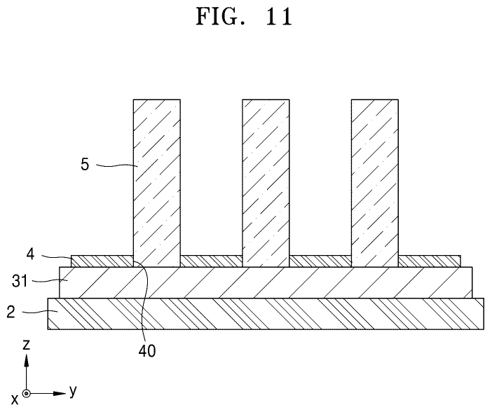

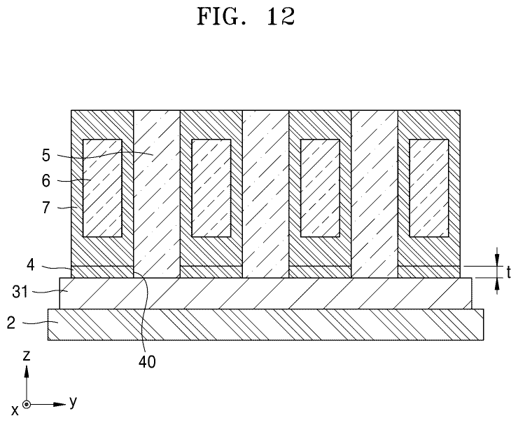

FIG. 9 is a flowchart illustrating a method of manufacturing a vertical structure semiconductor device according to an embodiment. FIG. 10 is a diagram illustrating an operation of forming a mask layer (S102). FIG. 11 is a diagram illustrating an operation of growing a plurality of channels (S103). FIG. 12 is a diagram illustrating an operation of forming a gate electrode 6 and an insulating layer (S104).

Referring to FIGS. 8 to 12, a method of manufacturing a vertical-structured semiconductor device according to an embodiment may include an operation of preparing a first electrode layer 31 including a transition metal element (S101). In this case, the transition metal element included in the first electrode layer 31 may include, for example, tungsten, but embodiments are not limited thereto.

The method of manufacturing a vertical-structured semiconductor device according to an embodiment may include an operation of forming a mask layer (S102). The operation S102 of forming the mask layer may be an operation of forming a mask layer exposing a portion of the surface of the first electrode layer 31 through a plurality of channel growth regions 40 on the first electrode layer 31. In the forming of the mask layer (S102), the mask layer 4 may be formed on the first electrode layer 31 such that the thickness t of the mask layer 4 is greater than 0 and less than or equal to about 10 nm. The plurality of channel growth regions 40 of the mask layer 4 may be regions for inducing the growth of the plurality of channels 5 to be described later.

The method of manufacturing a vertical-structured semiconductor device according to an embodiment may include an operation of growing the plurality of channels (S103). The growing of the plurality of channels (S103) may include growing the plurality of channels by supplying a precursor including a chalcogen element on the plurality of channel growth regions 40. Here, the plurality of channels 5 may include a transition metal dichalcogenide, and the transition metal dichalcogenide included in the plurality of channels 5 may include the same transition metal element as the transition metal element of the first electrode layer 31.

The method of manufacturing a vertical-structured semiconductor device according to an embodiment may include an operation of forming a gate electrode and a gate insulating layer (S104). In the forming of the gate electrode and the gate insulating layer (S104), the number of gate electrodes 6 may be adjusted and formed according to a process necessity.

The method of manufacturing a vertical-structured semiconductor device according to an embodiment may include an operation of forming a second electrode layer on the plurality of channels 5 (S105). In the forming of the second electrode layer (S105), the second electrode layer 32 may be formed so that the first electrode layer 31, the channels 5, and the second electrode layer 32 are arranged in a vertical direction in a line.

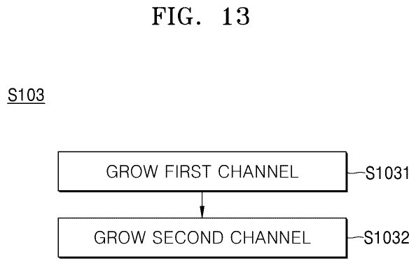

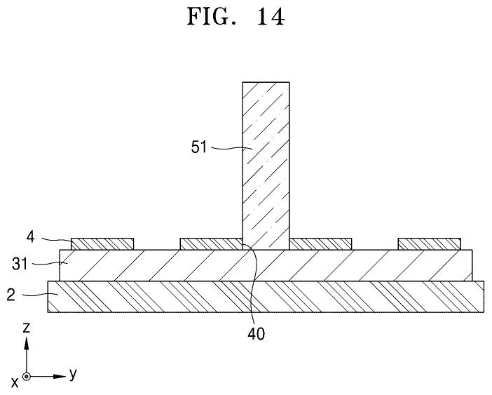

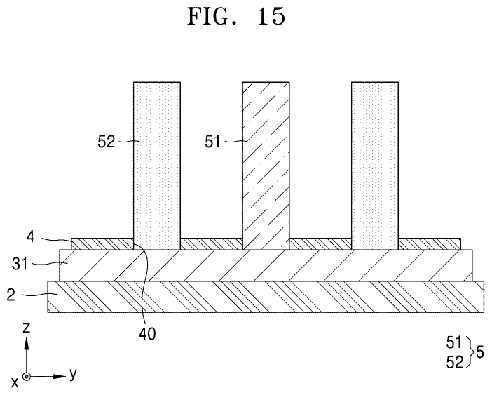

FIG. 13 is a flowchart illustrating an operation of forming a plurality of channels (S103) in a method of manufacturing a vertical structure semiconductor device according to an embodiment. FIG. 14 is a diagram illustrating an operation (S1031) of growing a first channel according to an embodiment. FIG. 15 is a diagram illustrating an operation (S1032) of growing a second channel according to an embodiment.

Referring to FIGS. 9 to 15, in the growing of the plurality of channels 5 (S103), the plurality of channels 5 may include a first channel 51 and a second channel 52. The first channel 51 may include a first transition metal dichalcogenide. The second channel 52 may include a second transition metal dichalcogenide different from the first transition metal dichalcogenide.

The operation S103 of growing the plurality of channels according to an embodiment may include the operation S1031 of growing the first channel. The operation S1031 of growing the first channel may be an operation S1031 of growing the first channel including the first transition metal dichalcogenide by supplying a first precursor including a first chalcogen element.

The operation S103 of growing the plurality of channels according to an embodiment may include the operation S1032 of growing the second channel. The operation S1032 of growing the second channel may be an operation of growing a second channel including the second transition metal dichalcogenide by supplying a second precursor including a second chalcogen element different from the first chalcogen element.

In this case, one of the first channel 51 and the second channel 52 may be a p-type semiconductor, and the other may be an n-type semiconductor. Further, each of the first channel 51 and the second channel 52 may include a transition metal element of the first electrode layer 31.

Since the channel grows directly across the channel growth region of the mask layer, it is possible to provide a vertical structure semiconductor device with excellent metal-substrate bonding between the electrode layer and the channel.

Since transition of the interface between the gate insulating layer and the channel is abrupt, it is possible to provide a vertical structure semiconductor device having excellent electrical characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A vertical structure semiconductor device comprising:
a first electrode layer including a transition metal element;
a mask layer including a metal oxide, the mask layer on the first electrode layer, the mask layer exposing a portion of a surface of the first electrode layer through a plurality of channel growth regions in the mask layer;
a plurality of channels each including a transition metal dichalcogenide, a first end of the plurality of channels being on the portion of the surface of the first electrode layer exposed by the plurality of channel growth regions;
a first gate electrode on the mask layer and surrounding each of the plurality of channels;
a gate insulating layer arranged on the mask layer, the gate insulating layer between the first gate electrode and the plurality of channels; and
a second electrode layer contacting a second end of the plurality of channels, the second end of the plurality of channels being opposite the first end of the plurality of channels, wherein
the transition metal dichalcogenide of the plurality of channels includes a transition metal element of the first electrode layer.

2. The vertical structure semiconductor device of claim 1, wherein the plurality of channels are grown on the first electrode layer by supplying a precursor including a chalcogen element on the plurality of channel growth regions of the mask layer.

3. The vertical structure semiconductor device of claim 2, wherein the transition metal element includes at least one of Mo, W, Nb, V, Ta, Ti, Zr, Hf, Co, Tc, Cu, Ni, Rh, Pd, Ir, Zn, Pt, and Re.

4. The vertical structure semiconductor device of claim 3, wherein the transition metal dichalcogenide of the plurality of channels includes at least one of S, Se, and Te.

5. The vertical structure semiconductor device of claim 4, wherein
the plurality of channels include a first transition metal dichalcogenide and a second transition metal dichalcogenide,
the second transition metal dichalcogenide is different from the first transition metal dichalcogenide.

6. The vertical structure semiconductor device of claim 5, wherein the first transition metal dichalcogenide and the second transition metal dichalcogenide include a same transition metal element.

7. The vertical structure semiconductor device of claim 6, wherein
one of the first transition metal dichalcogenide and the second transition metal dichalcogenide includes a p-type semiconductor, and
an other of the first transition metal dichalcogenide and the second transition metal dichalcogenide includes an n-type semiconductor.

8. The vertical structure semiconductor device of claim 4, wherein a thickness of the mask layer is greater than 0 and less than or equal to 10 nm.

9. The vertical structure semiconductor device of claim 8, wherein the metal oxide of the mask layer includes at least one of Hf, Al, and Zr.

10. The vertical structure semiconductor device of claim 9, wherein the gate insulating layer includes a same metal oxide as the metal oxide of the mask layer.

11. The vertical structure semiconductor device of claim 4, wherein the plurality of channels include at least one of nano rods and nano sheets.

12. A method of manufacturing a vertical structure semiconductor device, the method comprising:
preparing a first electrode layer including a transition metal element;
forming a mask layer on the first electrode layer, the mask layer exposing a portion of a surface of the first electrode layer through a plurality of channel growth regions;
growing a plurality of channels by supplying a precursor including a chalcogen element on the plurality of channel growth regions;
forming a gate electrode and a gate insulating layer on the mask layer; and
forming a second electrode layer on the plurality of channels, wherein
the plurality of channels include a transition metal dichalcogenide including the transition metal element of the first electrode layer.

13. The method of claim 12, wherein the transition metal element includes at least one of Mo, W, Nb, V, Ta, Ti, Zr, Hf, Co, Tc, Cu, Ni, Rh, Pd, Ir, Zn, Pt, and Re.

14. The method of claim 13, wherein the transition metal dichalcogenide includes at least one of S, Se, and Te.

15. The method of claim 14, wherein
the plurality of channels include a first transition metal dichalcogenide and a second transition metal dichalcogenide, and
the second transition metal dichalcogenide is different from the first transition metal dichalcogenide.

16. The method of claim 15, wherein the growing the plurality of channels comprises:
growing a first channel including the first transition metal dichalcogenide by supplying a first precursor including a first chalcogen element; and
growing a second channel including the second transition metal dichalcogenide by supplying a second precursor including a second chalcogen element, wherein
the second chalcogen element is different from the first chalcogen element.

17. The method of claim 16, wherein
one of the first channel and the second channel includes a p-type semiconductor and
an other of the first channel and the second channel includes an n-type semiconductor.

18. The method of claim 17, wherein each of the first channel and the second channel includes the transition metal element of the first electrode layer.

19. The method of claim 12, wherein
in the forming the mask layer, a metal oxide including at least one of Hf, Al, and Zr is formed on the first electrode layer.

20. The method of claim 19, wherein
in the forming the mask layer, the mask layer is formed on the first electrode layer, and
a thickness of the mask layer is greater than 0 and less than or equal to 10 nm.
